(19) United States
(12) Patent Application Publication
(10) Pub. No.: US 2014/0303906 A1
(43) Pub. Date: Oct. 9, 2014

(54) SYSTEM AND METHOD FOR DETECTING DETERIORATION OR A CUT IN A CABLE FOR CONVEYING SIGNALS

(71) Applicant: Bernard Charlot, Toulouse (FR)

(72) Inventor: Bernard Charlot, Toulouse (FR)

(73) Assignee: THALES, Neuilly-sur-Seine (FR)

(21) Appl. No.: 14/008,534

(22) PCT Filed: Mar. 22, 2012
(86) PCT No.: PCT/EP12/55065

§ 371 Date: Feb. 21, 2014

(30) Foreign Application Priority Data
Mar. 31, 2011 (FR) 1100962

(51) Int. Cl. G01R 31/08; G01M 11/00

(52) U.S. Cl. CPC G01R 31/08; G01M 11/33; G01N 2021/9511
USPC 702/36; 702/59

(57) ABSTRACT

A system and a method for detecting deterioration of or cuts in a cable for transmitting signals, includes at least at a first end of the cable a transceiver, at least at a second end of the cable a transceiver, and means for synchronization of the signals transmitted by the transceivers, and the system further includes at least processing means adapted to determine the times of non-reception of the signal at each end of said cable.

The invention concerns a system and a method for detecting an area in which deterioration, a cut or any physical defect preventing the correct transmission of electrical signals has occurred and the time at which the problem appeared. It is used for cables of great length, of the order of a few kilometers, for example.

It applies to electrical cables conveying electrical signals and also to optical fibers conveying optical signals.

It can be used in the field of electrical networks, rail networks, telecommunications networks, either terrestrial networks or networks implemented on ships.

In large electrified networks, fast location of the location of the area or the place at which a cable has been cut or has deteriorated is a major concern:
in the case of a cut made in order to steal the cable, rapid intervention can make it possible to prevent the theft and to apprehend its perpetrators,
in the case of an accidental or malicious cut or deterioration that is fortuitous, the immediate knowledge of the location or the area of the cut or deterioration enables the intervention of maintenance teams to be optimized and therefore the duration of the incident and thus the impact on the service provided to be minimized.

Although detection of the cut is easy because it is reflected in an absence of signal transmission, locating it is difficult, especially if the cable is not visually accessible. In all cases, finding the cut or deterioration by visual inspection is time-consuming.

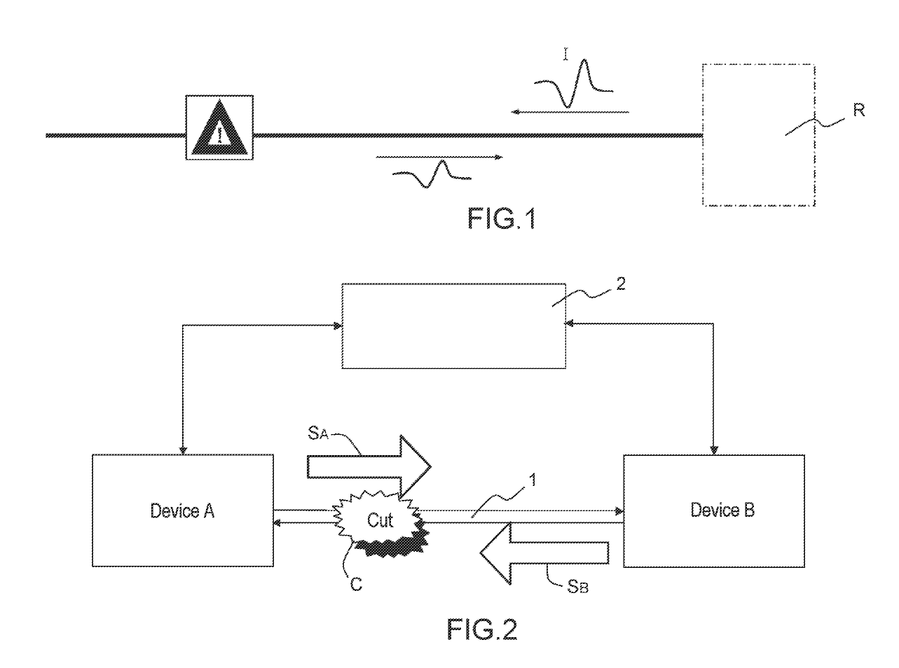

An existing industrial solution is to use an electrical reflectometer R emitting pulses I, as shown in FIG. 1.

This device is based on the reflection of an electrical pulse at any cable impedance variation front, in particular a cut. The various drawbacks of this technology are as follows:
it is inherently unable to function in parallel with the transmission of energy in the cable except in special cases; the cable must therefore be totally disconnected; this is therefore not a surveillance technique but merely a way of preparing the repair;
the measured length of the cable is limited by the physical principle employed, usually to a few thousand meters maximum; and
the precision of the location decreases with the length of the cable; it is typically 0.2% of the length.

In the prior art there is also described an approach that employs signals from Global Positioning System (GPS) satellites. This technique exploits the fact that if an incident occurs in a network the arcing caused by the fault is followed immediately by two high-tension pulses that propagate on either side of the fault. The common signal processing electronics are then synchronized with the GPS clock by equipping each end of the cable with a shock wave detector and a local GPS antenna. Each local processing station is then connected either via modem or via optical fiber to a main processing station that performs the appropriate calculations. This pre-location method applies as such to networks with no derivation. This technology thus uses the signals generated by breaking a cable.

The technical teaching of the document US 2006/012374 relates to a system in which a fault in a power system generates waves that propagate a great distance across the system from the point at which the fault occurred at speeds close to the speed of light. These waves are reflected at points at which the impedance of the system changes.

The technical teaching of the document US 2004/039976 is to modify the original data signal using DSSS techniques to spread the original signal and render its level low or comparable to noise. This method enables the test to be performed on the wires that are being used. The method thus uses a signal external to the system.

The growth of cable theft representing a very high cost (losses of millions of Euros), the operators or industrial companies concerned are constantly on the look out for fast and effective detection methods. Similarly, intentional or non-intentional deterioration of equipment generates malfunctions and therefore higher system operating costs.

The idea behind the present patent application is based on a new approach enabling instantaneous location of the position of the cut or the place at which an electrical cable, possibly a very long cable, for example a cable several tens of kilometers long, has deteriorated. This may also be applied to any cable conveying physical signals, such as optical fibers, etc.

The solution is notably based on the application of spatial location techniques employing synchronization between two points or nodes of the network.

The invention concerns a system for detecting deterioration of or cuts C in a cable for transmitting signals between at least one first device A and at least one second device B,
said first device A is disposed at a first end of the cable and includes at least a transceiver, synchronization means, means for communication between the first device A and the second device B, regardless of the state of the cable, calculation means connected to the transceiver, the transmitter is adapted to transmit a signal S_{A} from A to B, and the receiver is adapted to measure a time of non-reception of a signal coming from the second device,
said second device B is disposed at a second end of the cable, said second device B including at least the following components: a transceiver, synchronization means, means for communication between A and B, regardless of the state of the cable, calculation means connected to the transceiver, the transmitter is adapted to transmit a signal S_{B} from B to A, and the receiver is adapted to measure a time of non-reception of the signal transmitted by A,
the means for communicating times of non-reception of the signals measured at the receivers are adapted to transfer the measured times of non-reception of the signal S_{B} at the first device A and of non-reception of the signal S_{A} at the second device B to said calculation means, said calculation means being adapted to determine the time t_{C} and the location X_{C} of the fault or the cut in the cable from the measured times (t_{rA}, t_{rB}) of non-reception of signals received at the calculation means.

The means for calculation of non-reception of the signal are adapted to execute at least the following steps, for example:

X_{A} is the curvilinear abscissa of A as measured along the cable, X_{B} is the curvilinear abscissa of B along the cable, considering a direction of increasing abscissa from B to A,
V is the average speed of propagation of a signal in the cable between A and B, considered constant or substantially constant,
X_{C} is the curvilinear abscissa of the point of deterioration or the cut C in the cable and t_{C} the cut time,
tr_{B} is the time of disappearance of the signal measured by the receiver B on the signal S_{A} and tr_{A} is the time of disappearance of the signal measured by the receiver A on the signal S_{B},
the location X_{C} of the cut C in the cable is given by:

X_{C}=(X_{A}+X_{B})/2+V·(tr_{B}−tr_{A})

and the cut time t_{C} is given by:

t_{C}=(tr_{A}+tr_{B})/2+(X_{B}−X_{A})/2V

The signals S_{A}, S_{B} transmitted by A and B may be CDMA signals.

The cable is a copper cable, for example.

In accordance with another embodiment the cable is an optical fiber and the signals transmitted to detect deterioration or cutting are optical signals.

The means for communication between the first device A and the second device B consist for example of a wireless telephone or any other digital communication means in order to send the information to the devices when the cable has deteriorated.

The synchronization means include a GPS receiver, for example.

The invention also concerns a method for detecting deterioration of or cuts C in a cable for transmitting signals, the method being employed in the system having any of the above features, characterized in that it includes at least the following steps:
transmitting simultaneously at least one first signal S_{A} from a first device A to a second device B and at least one second signal S_{B} from the second device B to the first device A, transmission of said signals being synchronized,
detecting the time tr_{B} at which there is absence of reception of the signal S_{A} at the receiver of B and the time tr_{A} of absence of reception of the signal S_{B} at the receiver of A,
determining from tr_{A} the time of non-reception of the signal measured by the receiver of A and from tr_{B} the time of non-reception of the signal measured by the receiver of B, the location X_{C} and the time t_{C} of the cut in or the deterioration of the cable.

The time t_{rA} of non-reception of the signal measured by the receiver of A and the time t_{rB} of disappearance of the signal measured by the receiver of B are measured using a threshold level value S below which the signals are no longer detectable, for example.

The method includes at least the following steps, for example:

X_{A} is the curvilinear abscissa of A along the cable, X_{B} is the curvilinear abscissa of B along the cable, considering a direction of increasing abscissa from B to A, V is the average speed of propagation of a signal in the cable between A and B, considered constant or substantially constant,
X_{C} is the curvilinear abscissa of the point of deterioration or the cut C in the cable and t_{C} is the cut time,
tr_{B} is the time of disappearance of the signal measured by the receiver of B on the signal S_{A} and tr_{A} is the time of disappearance of the signal measured by the receiver of A on the signal S_{B},
the location X_{C} of the cut C in the cable is given by:

X_{C}=(X_{A}+X_{B})/2+V·(tr_{B}−tr_{A})

and the cut time t_{C} is given by:

t_{C}=(tr_{A}+tr_{B})/2+(X_{B}−X_{A})/2V

CDMA signals may be used and the last symbols received by at least the first device A and at least the second device B may be detected to determine the area of the cut in or the deterioration of the cable.

The system and the method in accordance with the invention may be used to detect cuts in or deterioration of a copper cable.

Other features and advantages of the present invention will become more apparent on reading the following description of one or more embodiments with reference to the appended figures, which represent:

FIG. 1, an example of prior art technology using a reflectometer,

FIG. 2, a theoretical diagram of the detection system in accordance with the invention,

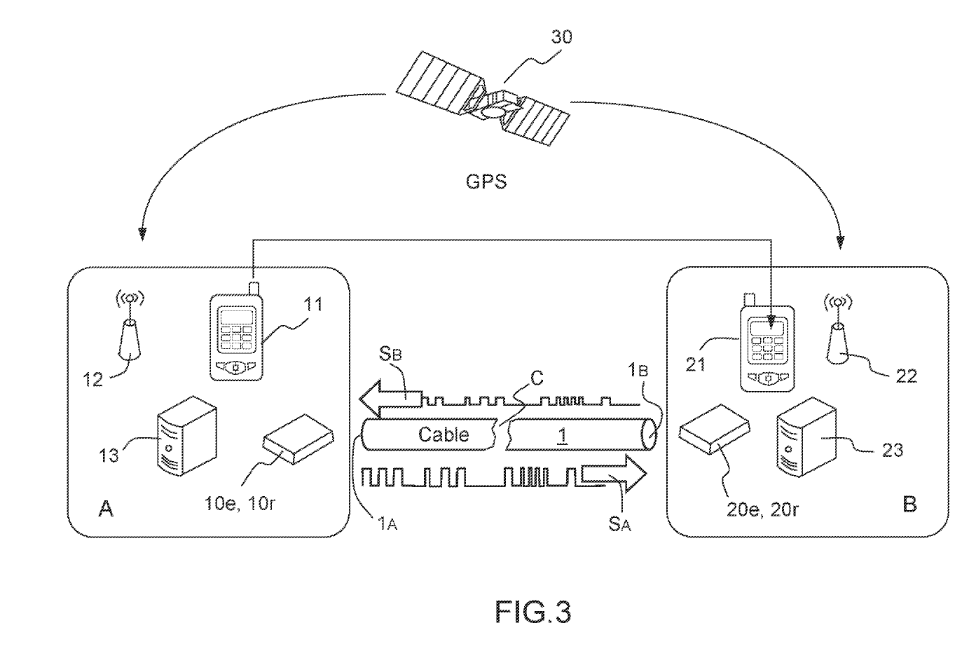

FIG. 3, one example of implementation of the system,

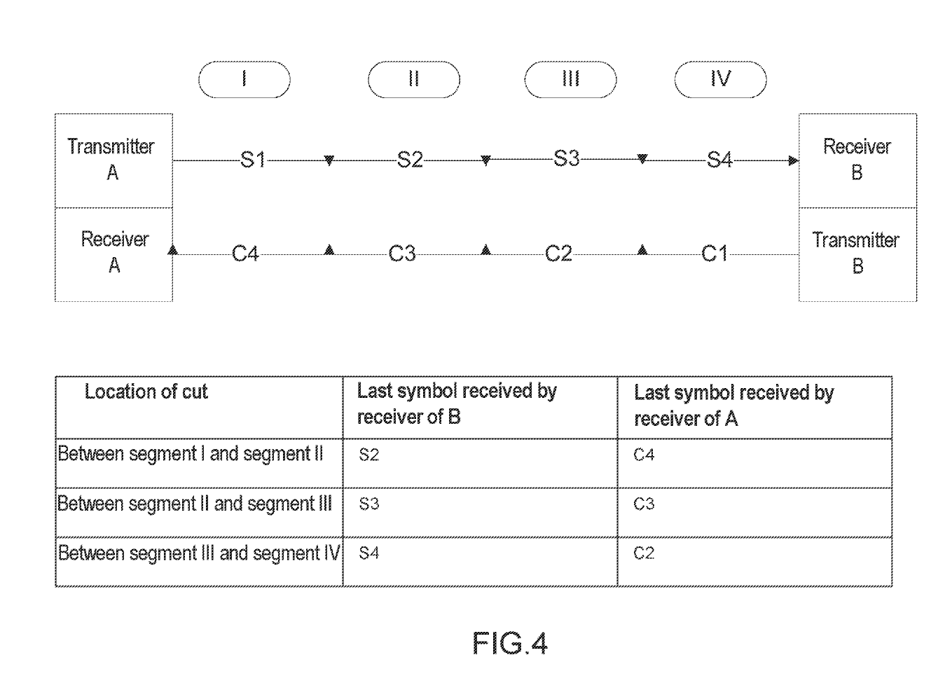

FIG. 4, an illustration of the measurement principle.

FIG. 2 shows the principle employed by the system and the method in accordance with the invention in the case of a cable 1 conveying electrical signals. Communication means 2 (11, 21 FIG. 3) enable information to be passed between two devices A and B regardless of the state of the cable, in particular if there is a cut or deterioration, as described in detail with reference to FIG. 3 in the context of a nonlimiting illustrative example. The device A transmits a first signal S_{A} to the device B and at the same time the device B transmits a second signal S_{B} to the device A. The transmission of the signals S_{A}, S_{B} is synchronized by appropriate synchronization means to obtain synchronized transmission of the signal S_{A} and the signal S_{B}. A possible cut is represented by the point C.

In some cases, the communication means can also have the function of synchronizing the transmission of signals between the devices.

Without departing from the scope of the invention, the synchronization system is for example based on a Global Navigation Satellite System (GNSS) other than the GPS, GALILEO, GLONASS system, or other constellations or multiple constellations.

It is also possible to use network synchronization means known to a person skilled in the art, like the standard Network Time Protocol (RFC 958). In this case, the devices A and B are connected to a network providing at least one NTP server. This notably enables decametric level precision to be obtained.

Another embodiment of the synchronization means consists in using two high-precision clocks, for example the rubidium or cesium atomic clock that features low drift over time. The clocks are synchronized before they are used and if necessary at regular intervals depending on their own drift and the required precision. The initial adjustment is effected by determining a common time difference relative to GPS time. The precision achieved can be very high (typically at the decimetric level) depending on the choice of clocks and the resynchronization period chosen.

To summarize, implementing the system and the method in accordance with the invention to be described in detail hereinafter requires at least two measurements to calculate the time t_{C} and the position X_{C} of a cut C in the cable 1 and the use of means for communicating information between A and B after cutting or disappearance of the signal received at the level of A and/or B. Implementing the method in accordance with the invention in fact necessitates combining the two measurements in a computer to enable calculation of a solution.

FIG. 3 represents one embodiment of the system and the method in accordance with the invention for detecting a fault or a cut affecting an electrical cable.

In this embodiment the system enabling detection of the time of non-reception of the signal at the level of a transmitter in order to determine the time and the area of the cut includes a cable 1 comprising at a first end 1_{A} the device A and at the second end 1_{B} the device B.

The device A comprises, for example:
a transceiver modem 10e, 10r notably having the function of transmitting a signal S_{A} from A to B over the cable 1 in which a cut may occur and receiving the measured times of non-reception of the signal S_{B} if the signals are no longer circulating in the cable,
means 11 for communication between the devices A and B that enable the transfer of data when the transmission of information via the cable is no longer possible,
means 12 for synchronizing the transmission of signals between A and B, and
a computer 13 connected to the receiver 10r in order to calculate the time and the area of the cut using the method in accordance with the invention to be described hereinafter.

The receiver 10r is adapted to capture and store the time of non-reception of the signal S_{B} transmitted by the device B to the device A.

The device B comprises, for example:
a transceiver modem 20e, 20r notably having the function of transmitting a signal S_{B} from B to A over the cable 1 on which a cut may occur and receiving the measured times of non-reception of the signal S_{A} if the signals are no longer circulating in the cable,
means 21 for communication between B and A that enable transfer of data when transmission via the cable is no longer possible,
synchronization means 22 enabling simultaneous transmission of the signal S_{B} and the signal S_{A},
a computer 23 connected to the receiver 20r in order to calculate the time and the area of the cut using the method in accordance with the invention to be described hereinafter.

The receiver modem 20r enables capture of the time of non-reception of the signal S_{A} that the device B would have received if there had been no cut in or deterioration of the cable 1.

The idea implemented in the method and the system in accordance with the invention is to monitor the times at which these signals S_{A} S_{B} are no longer received by the receiver part of the modem in the receivers 10r, 20r.

Transmission between the first device A and the second device B may be synchronized by the synchronization means 12, 22, for example, which employ signals transmitted by the GPS (Global Positioning System) constellation 30 in order to determine a common time difference relative to GPS time. The synchronization means are adapted to effect simultaneous synchronization of the signals S_{A} S_{B} between the first device A and the second device B.

The means for communication of information or signals when the cable has deteriorated are digital communication means, a mobile telephone or any other communication network, for example.

In order to use the method in accordance with the invention, the value of the speed at which the signals circulate is known. In order to circumvent any defects of homogeneity in the structure of the cable it is possible to take as the speed value an average speed value.

To this end, knowing the geometrical characteristics of the cable, its length, etc. there is determined during an initialization phase the travel time tp of a signal transmitted from the device A to the device B or vice versa, after which the length Lc of the cable is divided by this travel time tp to obtain the average speed V.

The characteristics of the cable may be known in advance or determined by appropriate devices known to a person skilled in the art.

In the example to be given to illustrate the method in accordance with the invention, there is a dimension to be measured corresponding to the curvilinear abscissa and a time ambiguity (two transmitting equipments) at each end 1A, 1B of the cable 1.

The frequency characteristics of the signals transmitted are chosen as a function of the nature of the cable examined, for example.

Use in the above device of the method in accordance with the invention as described with reference to FIG. 3 includes the following steps, for example:
a) the transmitter 10e of the device A transmits a first signal S_{A} from A to the device B and at the same time the transmitter 20e of B transmits a second signal S_{B} from B to the device A,
b) the transmission of the signals S_{A} and S_{B} is synchronized by the synchronization means 12, 22 (A and B are provided with signal transceivers closely synchronized with each other by the aforementioned ad hoc means),
c) in the case of deterioration C of the cable 1 sufficient to prevent the transmission of the signals, or in the case of a cut, the devices A and B do not receive signals; it is this indication of non-reception of the signal that is used in the method to determine the location of the break or deterioration and the time at which this problem arose, on the following basis:
a) considering the cable portion between A and B, and taking the curvilinear abscissa X measured along this cable, counted as positive from B to A, this abscissa increasing from B to A, for example;
b) X_{A} is the curvilinear abscissa of A and X_{B} is the curvilinear abscissa of B;
c) V is the average speed of propagation of the signal in the cable between A and B, considered constant and known in advance;
d) C is a point at which the cable is cut, X_{C} the curvilinear abscissa of C and t_{C} the time of the cut or deterioration of the cable; X_{C} and t_{C} are the unknowns to be determined.

The method proposes to measure the time of disappearance of the signals S_{A}, S_{B} when the cable is cut or deteriorates:
e) tr_{B} is the time of disappearance or of non-reception of the signal measured by the receiver of B on the signal S_{A};
f) tr_{A} is the time of disappearance or of non-reception of the signal measured by the receiver of A on the signal S_{B}.

The times tr_{B}, tr_{A} of disappearance of the signals may be determined using a threshold value S from which the signal can no longer be detected.

The following two propagation equations then apply in the case of an abscissa increasing from B to A:

for the signal S_{A}: X_{B}=X_{C}−V·(tr_{B}−t_{C}) (1)

for the signal S_{B}: X_{A}=X_{C}+V·(tr_{A}−t_{C}) (2)

which gives the location X_{C} of the cut C in the cable 1

X_{A}+X_{B}=2X_{C}+V(tr_{A}−tr_{B}) (3)

i.e.

X_{C}=(X_{A}+X_{B})/2+V·(tr_{B}−tr_{A}) (3′)

and the cut time t_{C}

X_{B}−X_{A}=−V(tr_{B}−t_{C})−V(tr_{A}−t_{C}) (4)

i.e.

(X_{B}−X_{A})/V=−tr_{A}−tr_{B}+2t_{C} (4′)

i.e.

t_{C}=(tr_{A}+tr_{B})/2+(X_{B}−X_{A})/2V (4″)

Taking by convention an abscissa increasing from A to B, it then suffices to consider the speed V′=−V.

The communication means may also consist in ultra high frequency (UHF) or very high frequency (VHF) radio transmission, a telephone line or some other cable connecting the two points.

The synchronization between the devices A and B may be provided by a GPS or Galileo receiver present in each device, a network synchronization device known to a person skilled in the art, possibly employing the cable itself; in this case, synchronization becomes useless after the cable is cut.

The signals used to detect the cut or the location and time of deterioration of the cable may be either the signal normally transmitted by the cable, of which this is the primary function, or ad hoc signals generated by the transmitter devices A and B and multiplexed by the cable. In the latter case, the use of transmission employing code division multiple access (CDMA) type coding, for example, is particularly suitable for preventing interference of the signals with each other and where applicable with the basic signal that the cable may convey.

The set of measurements may include either the precise measurement of the time of loss of reception of the signal in each device after the cable is cut or the determination of the last symbol received in the context of CDMA transmission.

FIG. 4 shows an embodiment of the method in accordance with the invention in the case of CDMA type transmission. The table gives the location of the cut as a function of the symbol received by the receiver of B and the symbol received by the receiver of A.

For example, in the figure the length of cable is divided into four segments I, II, III, IV. A transmits a signal consisting of pulses S1, S2, S3, S4 in the direction of B and B transmits a signal consisting of pulses C1, C2, C3, C4. The signals are transmitted synchronously.

The table below gives the location of the cut in or the deterioration of the cable as a function of the last symbols received by the receiver of B and the receiver of A, respectively. It is necessary to know the pair formed by the last symbols received at either end of the cable under surveillance in order to resolve the time/position ambiguity that would remain in the event of knowing only one of the symbols: for example, reception of S2 (see table) as the last symbol by the receiver of B could correspond to a cut in a part of the cable other than between the segment I and the segment II, but produced at a time different from that such that the last symbol conjointly received by the receiver of A is the symbol C4.

| | Last symbol | Last symbol |
|---|---|---|
| | received by | received by |
| Location of cut | receiver of B | receiver of A |
| Between segment I and | S2 | C4 |
| segment II | | |
| Between segment II and | S3 | C3 |
| segment III | | |
| Between segment III | S4 | C2 |
| and segment IV | | |

The system and the method in accordance with the invention notably offer the following advantages:
Instantaneous provision of the position of the cut,
Precision independent of the length of the cable,
Independence of the method of the nature of the cable under surveillance,
Compatibility with the transmission of other signals in the cable,
A device usable for the transmission of service information.

1. A system for detecting deterioration of or cuts C in a cable for transmitting signals between at least one first device A and at least one second device B, comprising:
said first device A being disposed at a first end of the cable and including at least a transceiver, synchronization means, means for communication between the first device A and the second device B, calculation means connected to the transceiver, the transmitter being adapted to transmit a signal S_{A} from A to B, the receiver being adapted to measure times of non-reception of a signal,
said second device B being disposed at a second end of the cable, said second device B including at least the following components: a transceiver, synchronization means, means for communication between A and B, calculation means connected to the transceiver, the transmitter being adapted to transmit a signal S_{B} from B to A, the receiver being adapted to measure times of non-reception of a signal, and
wherein the means for communicating times of non-reception of the signals measured at the receivers are adapted to transfer the measured time of non-reception of the signal S_{B} at the first device A and the measured time of non-reception of the signal S_{A} at the second device B to said calculation means, said calculation means being adapted to determine the time t_{C} and the location X_{C} of the fault or the cut in the cable from the measured times of non-reception of signals received at the calculation means.

2. The system as claimed in claim 1, wherein the means for calculation of non-reception of the signal are adapted to execute at least the following steps:
X_{A} is the curvilinear abscissa of A as measured along the cable, X_{B} is the curvilinear abscissa of B along the cable, considering a direction of increasing abscissa from B to A,
V is the average speed of propagation of a signal in the cable between A and B, considered constant or substantially constant,
X_{C} is the curvilinear abscissa of the point of deterioration or the cut C in the cable and t_{C} is the cut time,
tr_{B} is the time of non-reception of the signal measured by the receiver B on the signal S_{A} and tr_{A} is the time of non-reception of the signal measured by the receiver A on the signal S_{B}
the location X_{C} of the cut C in the cable is given by:
X_{C}=(X_{A}+X_{B})/2+V·(tr_{B}−tr_{A})
and the cut time t_{C} is given by:
t_{C}=(tr_{A}+tr_{B})/2+(X_{B}−X_{A})/2V.

3. The system as claimed in claim 1, wherein the signals S_{A}, S_{B} transmitted by A and B are CDMA signals.

4. The system as claimed in claim 1, wherein the cable is a copper cable.

5. The system as claimed in claim 1, wherein the cable is an optical fiber and the signals transmitted to detect deterioration or cutting are optical signals.

6. The system as claimed in claim 1, wherein the means for communication between the first device A and the second device B consist of a wireless telephone.

7. The system as claimed in claim 1, wherein the synchronization means include a GPS receiver.

8. A method for detecting deterioration of or cuts C in a cable for transmitting signals, the method being employed in the system as claimed in claim 1, further comprising:
Transmitting simultaneously at least one first signal S_{A} from a first device A to a second device B and at least one second signal S_{B} from the second device B to the first device A, transmission being synchronized,
Detecting the time at which there is absence of reception of the signal S_{A} at the receiver of B and absence of reception of the signal S_{B} at the receiver of A,
Determining from tr_{A} the time of disappearance or non-reception of the signal measured by the receiver of A and from tr_{B} the time of disappearance or non-reception of the signal measured by the receiver of B, the location X_{C} and the time t_{C} of the cut in or the deterioration of the cable.

9. The method as claimed in claim 8, wherein the time tr_{A} of disappearance of the signal measured by the receiver A and the time tr_{B} of disappearance of the signal measured by the receiver B are measured using a threshold level value S below which the signals are no longer detectable.

10. The method as claimed in claim 8 further comprising:
X_{A} is the curvilinear abscissa of A as measured along the cable, X_{B} is the curvilinear abscissa of B along the cable, considering a direction of increasing abscissa from B to A,
V is the average speed of propagation of a signal in the cable between A and B, considered constant or substantially constant,
X_{C} is the curvilinear abscissa of the point of deterioration or the cut C in the cable and t_{C} is the cut time,
tr_{B} is the time of disappearance of the signal measured by the receiver of B on the signal S_{A} and tr_{A} is the time of disappearance of the signal measured by the receiver of A on the signal S_{B}
the location X_{C} of the cut C in the cable is given by:
X_{C}=(X_{A}+X_{B})/2+V·(tr_{B}−tr_{A})
and the cut time t_{C} is given by:
t_{C}=(tr_{A}+tr_{B})/2+(X_{B}−X_{A})/2V.

11. The method as claimed in claim 8, wherein CDMA signals are used and the last symbols respectively received by at least the first device A and at least the second device B are detected to determine the area of the cut in or the deterioration of the cable.

12. The use of the system as claimed in claim 1 to detect cuts in or deterioration of copper cable.
